(19) United States
(12) Patent Application Publication
(10) Pub. No.: US 2014/0295085 A1
(43) Pub. Date: Oct. 2, 2014

(54) METHOD FOR MANUFACTURING DONOR SUBSTRATE

(71) Applicants: Ji-Myoung YE, Yongin-City (KR); Sang-Woo PYO, Yongin-City (KR); Ji-Hwan YOON, Yongin-City (KR); Ha-Jin SONG, Yongin-City (KR); Byeong-Wook YOO, Yongin-City (KR); Bum-Suk LEE, Yongin-City (KR); Ji-Young KWON, Yongin-City (KR)

(72) Inventors: Ji-Myoung YE, Yongin-City (KR); Sang-Woo PYO, Yongin-City (KR); Ji-Hwan YOON, Yongin-City (KR); Ha-Jin SONG, Yongin-City (KR); Byeong-Wook YOO, Yongin-City (KR); Bum-Suk LEE, Yongin-City (KR); Ji-Young KWON, Yongin-City (KR)

(21) Appl. No.: 13/940,719

(22) Filed: Jul. 12, 2013

(30) Foreign Application Priority Data
Mar. 27, 2013 (KR) 10-2013-0033071

(51) Int. Cl. H01L 51/56

(52) U.S. Cl. CPC H01L 51/56
USPC 427/299; 427/444

(57) ABSTRACT

A method for manufacturing a donor substrate according to an exemplary embodiment of the present invention includes: providing a base member; forming a coating layer on one surface of the base member; hardening the coating layer; and detaching the coating layer from the base member.

### CLAIM OF PRIORITY

This application claims priority to and the benefit of Korean Patent Application No. 10-2013-0033071 filed in the Korean Intellectual Property Office on Mar. 27, 2013, the entire contents of which are incorporated herein by reference.

### BACKGROUND OF THE INVENTION

1. Field of the Invention

The present invention relates to a method for manufacturing a donor substrate, and more particularly, to a method for manufacturing a donor substrate used when forming an organic layer pattern by using a laser thermal transfer method.

2. Description of the Related Art

An organic light emitting diode (OLED) display is a self-emitting type display device for emitting light through recombination of a hole injected from an anode and an electron injected from a cathode on an organic emission layer while the light is dissipated. Also, the OLED display has received attention as the next generation display device for portable electronic devices by representing high quality characteristics such as low electric power consumption, high luminance, a wide viewing angle, and a high reaction speed.

The OLED display includes an anode, a cathode and organic layers interposed between the anode and the cathode. The organic layers includes at least an emission layer and may further include a hole injection layer (HIL), a hole transport layer (HTL), an electron transport layer (ETL), and an electron injection layer (EIL) in addition to the emission layer. The organic electroluminescence element is divided into a polymeric organic electroluminescence element and a low molecular organic electroluminescence element according to the organic layer, particularly, a material of which the emission layer is made.

The emission layer is required to be patterned, and examples of a method for patterning an emission layer include a method by using a fine metal mask in the case of a low molecular organic electroluminescence element, and an ink-jet printing method or a laser induced thermal imaging (LITI) method in the case of a polymeric organic electroluminescence element. In the laser induced thermal imaging among the above methods, a laser beam generated from a laser beam generator is patterned by using a mask pattern, and the patterned laser beam is irradiated onto a donor substrate, including a transfer layer, to transfer a portion of the transfer layer to an OLED display, thereby forming an emission layer on the OLED display. The method has advantages of precisely patterning the organic layer, being used in a large area, and implementing a high-resolution.

The method for forming the organic layer by using the laser induced thermal imaging is required to have at least a light source, an acceptor substrate (organic light emitting element substrate), and a donor substrate. The donor substrate includes a base member, a light-to-heat conversion (LTHC) layer, and a transfer layer.

The light irradiated from the light source is absorbed into the light-to-heat conversion layer on the donor substrate so as to be converted into heat energy. The converted heat energy may change adhesion force among the light-to-heat conversion layer, the transfer layer and the acceptor substrate, such that the material of which the transfer layer formed on the donor substrate is made is transferred onto the acceptor substrate, and an organic emission layer is patterned on the acceptor substrate.

A cleaning process is performed in order to remove dust on the base member prior to forming the transfer layer made of an organic material on the base member on which the light-to-heat conversion layer is formed. Although the cleaning process is performed, it is difficult to remove fine dust size of 3 μm or less, and accordingly, there has been a problem in that a phenomenon that the transfer layer locally lifted up occurs when forming the transfer layer.

The above information disclosed in this Background section is only for enhancement of understanding of the background of the invention, and therefore it may contain information that does not form the prior art that is already known in this country to a person of ordinary skill in the art.

### SUMMARY OF THE INVENTION

The present invention has been developed in an effort to provide a method for manufacturing a donor substrate having the advantages of removing fine dust on a base member of the donor substrate and preventing a transfer layer from slightly and locally being lifted up.

An exemplary embodiment of the present invention provides a method for manufacturing a donor substrate including: providing a base member; forming a coating layer on one surface of the base member; hardening the coating layer; and detaching the coating layer from the base member.

The forming pf the coating layer may be performed by depositing a coating material.

The coating material may be an acryl-based resin.

The hardening of the coating layer may be performed using ultraviolet (UV).

A wavelength of ultraviolet (UV) may be in a range of 200 to 400nm.

The coating layer may have a thickness of 10 μm or more.

In the detaching of the coating layer, the coating layer may be detached by winding the coating layer onto a detaching roller.

Each of the steps may be performed in a vacuum atmosphere.

The method may further include lowering a surface energy of the base member prior to the providing of the base member.

In the lowering of the surface energy of the base member, the surface of the base member may be fluorinated.

The method may further include coating a transfer layer onto a surface of the base member after the detaching the coating layer.

According to an exemplary embodiment of the present invention, it is possible to remove fine dust on a base member of a donor substrate and prevent the transfer layer from being locally lifted up.

Therefore, it is possible to decrease an inferiority rate of the manufactured donor substrate and narrow a fine air gap that may be made between the donor substrate and an acceptor substrate in a transfer process, thereby increasing transferring efficiency.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIGS. 1 to 4 are schematic diagrams sequentially illustrating a method for manufacturing a donor substrate according to an exemplary embodiment of the present invention.

FIG. 5 is a side view of a donor substrate manufactured by a method for manufacturing a donor substrate according to the exemplary embodiment of the present invention.

FIGS. 6A to 6C are process views illustrating processes of manufacturing an organic light emitting diode (OLED) display using a donor substrate manufactured by a method for manufacturing a donor substrate according to the exemplary embodiment of the present invention.

FIG. 7 is a cross-sectional view of an organic light emitting diode (OLED) display manufactured using a donor substrate.

### DETAILED DESCRIPTION OF THE EMBODIMENTS

Hereafter, a method for manufacturing a donor substrate according to an exemplary embodiment of the present invention will be described in detail with reference to the accompanying drawings.

However, the present invention is not limited to the embodiments disclosed in the following, but can be implemented in many different ways, and these exemplary embodiments may be provided so that this disclosure will be thorough and complete, and will fully convey the scope of the invention to those skilled in the art.

It is also noted that like reference numerals denote like elements throughout the drawings.

In the drawings, the thicknesses of layers, films, panels, regions, etc., are exaggerated for clarity.

In addition, the thickness of layers and regions is exaggerated for efficient description of technical contents.

It will be understood that, when an element is referred to as being “on˜” another element, it can be directly connected to the other element or may be indirectly connected to the other element with element(s) interposed therebetween.

An element is referred to as being “on˜” throughout the specification, which refers to being located at an upper or lower side of an object, and does not definitely refer to being located at an upper side with respect to the direction of gravity.

In addition, unless explicitly described to the contrary, the word “comprise” and variations such as “comprises” or “comprising” will be understood to imply the inclusion of stated elements, not the exclusion of any other elements.

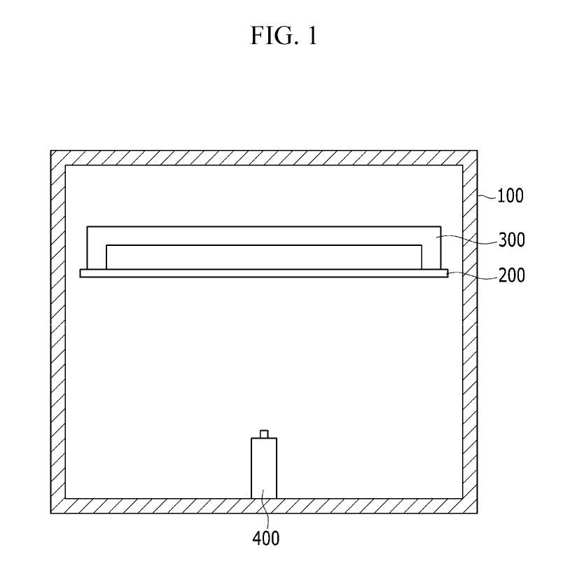

FIGS. 1 to 4 are schematic diagrams sequentially illustrating a method for manufacturing a donor substrate according to an exemplary embodiment of the present invention.

Referring to FIGS. 1 to 4, a method for manufacturing a donor substrate according to an exemplary embodiment of the present invention includes: providing a base member, forming a coating layer, hardening the coating layer; and detaching the coating layer.

First, a base member 200 is provided. The base member 200 is mounted on and fixed to a holder 300. The base member 200 is a light-to-heat conversion layer absorbing light and converting the light into heat energy, and a film for supporting a transfer layer configured of a material to be patterned. The light-to-heat conversion layer may be formed on the base member 200 according to an exemplary embodiment of the present invention

As illustrated in FIG. 1, the base member 200 is carried in a processing chamber 100 and a series of processes to be described may be performed in the processing chamber 100. The processing chamber 100 includes a reaction space therein, and may further include a gate valve (not illustrated) for carrying in and out an object to be processed, a vacuum pump (not illustrated) for lowering inner pressure by ejecting gas into the reaction space, and venting means (not illustrated) for increasing inner pressure in the vacuum chamber by injecting constant gas into the vacuum chamber. The method for manufacturing a donor substrate according to the exemplary embodiment of the present invention may be performed in a vacuum atmosphere in which an appropriate degree of vacuum is maintained.

A surface energy of the base member 200 may be lowered before the base member 200 is disposed in the processing chamber 100. Since a surface energy of the base member 200 is lowered, the coating layer 204 formed on a surface of the base member 200 is easily detached from the base member 200 in a following process. In a process of lowering the surface energy, the surface of the base member 200 may be fluorinated.

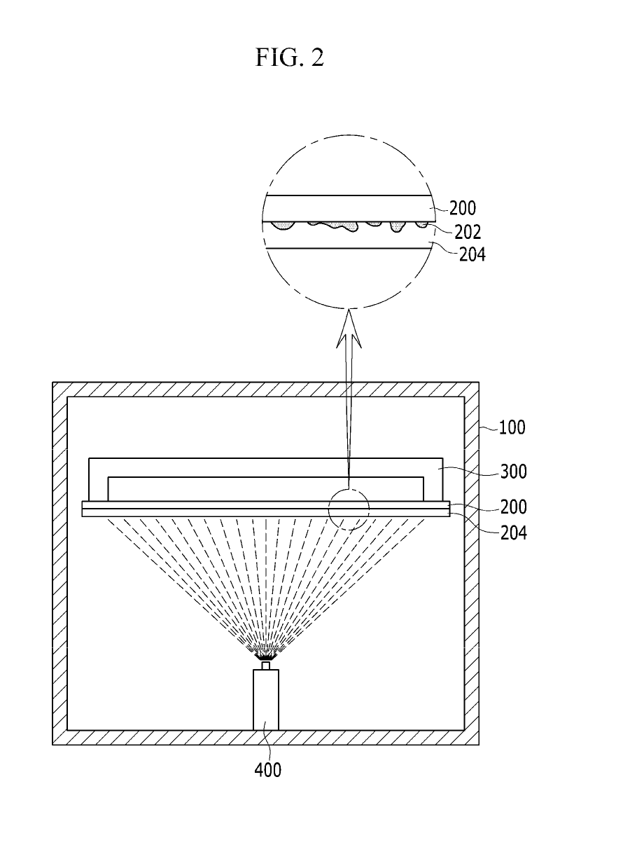

The coating layer 204 (FIG. 2) is formed on one surface of the base member 200. The coating layer 204, which is a means for collecting and removing foreign particles 202 attached on one surface of the base member 200, may be deposited on one surface of the base member 200 by heating and evaporating a solid coating material or a liquid coating material.

For instance, as illustrated in FIG. 2, a deposition apparatus 400 spraying a coating material is disposed so as to face one surface of the base member 200 on which the foreign particles 202 are removed, and the coating material may be deposited on one surface of the base member 200 by evaporating the coating material. In a case where the light-to-heat conversion layer is provided on the base member 200, one surface of the base member including the light-to-beat conversion layer, is disposed so as to face the deposition apparatus 400.

The deposition apparatus 400 may use a deposition source for forming an organic thin film on the substrate by evaporating the organic material. The deposition source includes a storage space capable of storing the deposition material, such as the organic material, therein. A heater, which heats and evaporates the stored deposition material while surrounding the external surface of the storage space, may be provided on an external surface of the storage space.

In the present exemplary embodiment, the coating material is deposited on one surface of the base member 200 so as to form the coating layer 204, such that the foreign particles 202 are collected on the coating layer 204.

The coating layer 204 has a thickness of 10 μm or more. In a case where the coating layer 204 has a thickness of below 10 μm, the foreign particle 202, which has a thickness of 3 μm or more, is not easily and completely removed from the base member 200 due to damage to the coating layer 204 which can occur at the time of detaching the coating layer 204.

Next, the coating layer 204 formed on one surface of the base member 200 is hardened. The process is to easily remove the coating layer 204 collecting the foreign particles 202 from the base member 200.

The coating material of which the coating layer 204 is made may include an acryl-based resin. At this time, the coating layer may be hardened by irradiating ultraviolet (UV).

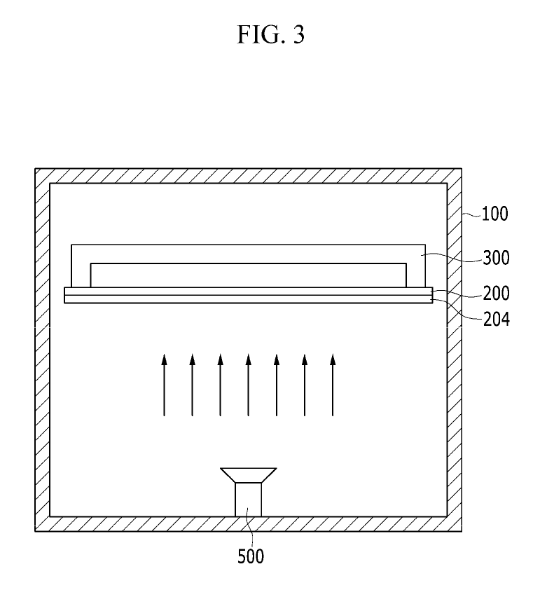

As illustrated in FIG. 3, a UV irradiation apparatus 500 is disposed so as to face the coating layer 204, and may irradiate the ultraviolet UV on the coating layer 204. Here, the wavelength of the UV may be in a range of 200 to 400 nm so as to harden the acryl-based resin.

Next, after hardening the coating layer 204, the coating layer 204 is detached and removed from the base member 200. Since the foreign particles 202 attached to the surface of base member 200 are collected by the coating layer 204, the foreign particle 202 may be removed by detaching the coating layer 204.

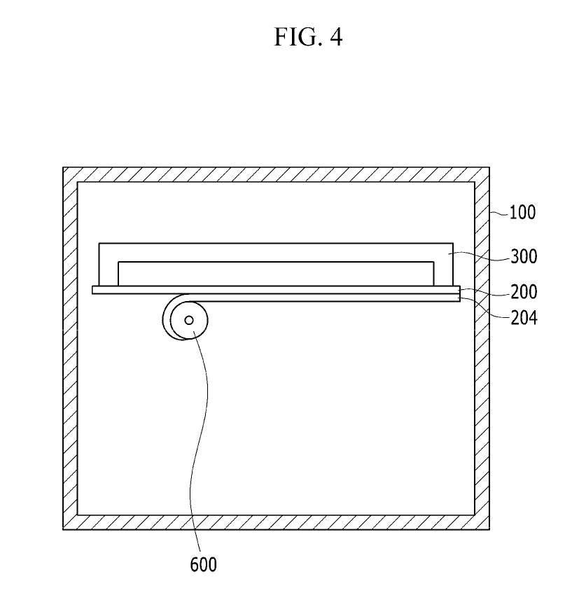

As illustrated in FIG. 4, the detaching of the coating layer 204 may be performed by being wound around a detaching roller 600.

Here, after one end of the coating layer 204 is fixed to the detaching roller 600, the coating layer 204 is sequentially detached while winding the coating layer 204 from one end to the other end. Since the coating layer 204 is sequentially removed from one end thereof, the coating layer 204 may be prevented from being damaged during detaching.

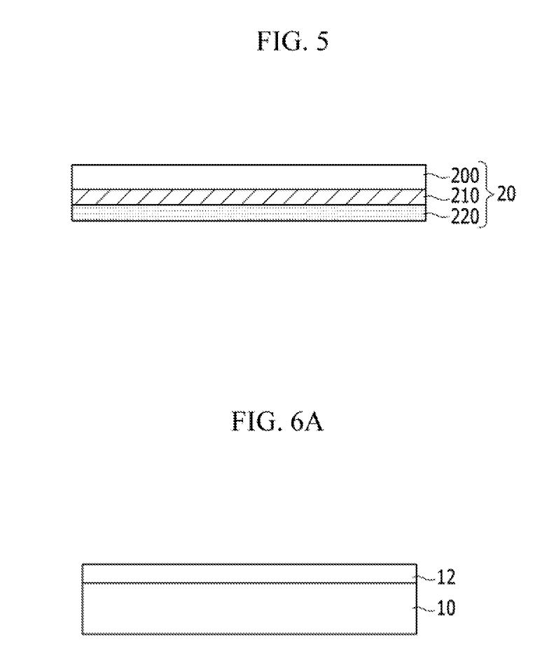

FIG. 5 is a side view of a donor substrate manufactured by a method for manufacturing a donor substrate according to an exemplary embodiment of the present invention.

Next, after detaching the coating layer 204, a transfer layer 220 may be coated onto a surface of the base member 200. Since the foreign particle 202 attached to the surface of base member 200 is removed while detaching the coating layer 204, the transfer layer 220 may be prevented from being lifted up from the surface of the base member 200.

As illustrated in FIG. 5, the light-to-heat conversion layer 210 may be interposed between the base member 200 and the transfer layer 220. The transfer layer 220 is formed on the light-to-heat conversion layer 210 so as to complete the donor substrate 20. The transfer layer 220 may be formed by a typical coating method, such as an extrusion method, a spin method, a knife coating method, a vacuum deposition method, and the like.

The donor substrate 20 may further include a plurality of layers containing various functions, such as a buffer layer (not illustrated), in addition to the base member 200, the light-to-heat conversion layer 210, and the transfer layer 200.

In a case where the transfer layer 200 is formed on a surface of the base member 200 by a vacuum deposition method, the transfer layer 220 may be formed by depositing a material for the transfer layer 220 onto a surface of the base member 200 without carrying out the base member 200 from the processing chamber 110 according to the exemplary embodiment of the present invention, and releasing a vacuum.

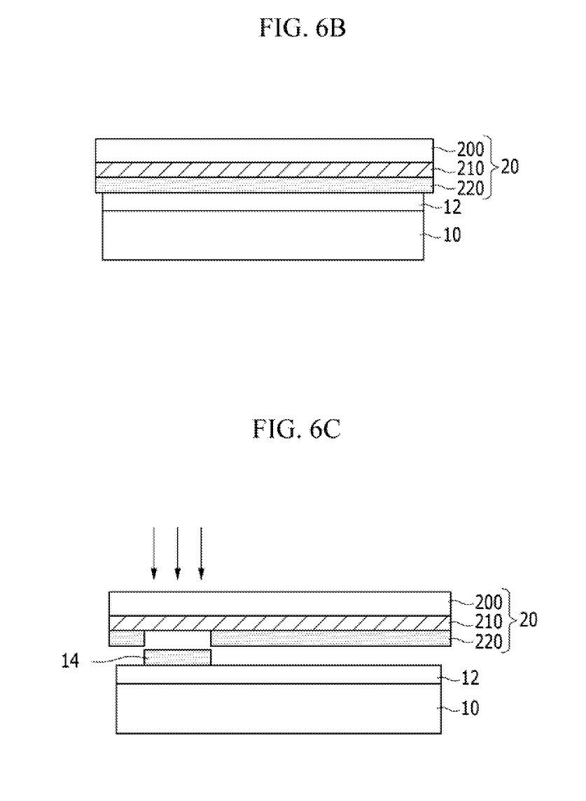

FIGS. 6A to 6C are process views illustrating processes of manufacturing an organic light emitting diode (OLED) display using a donor substrate manufactured by a method for manufacturing a donor substrate according to an exemplary embodiment of the present invention.

As illustrated in FIG. 6A, an acceptor substrate 10 on which a first electrode layer 12 is formed is provided. Here, a driving transistor, a protective layer, the first electrode layer 12 and the like may be laminated onto the acceptor substrate 10. A detailed description will be set forth below.

As illustrated in FIG. 6B, the light-to-heat conversion layer 210 and the transfer layer 220 of the donor substrate 20 are sequentially laminated onto the base member 200.

Here, the transfer layer 220, which is an organic material formed on the acceptor substrate 10 by a thermal transfer method, may be one of organic light-emitting materials of red (R), green (G), and blue (B). The transfer layer 220 may further include at least one of a hole transporting material, an electron transporting material and a both charges-transporting material with organic emission material having separate colors.

Furthermore, the transfer layer 220 is formed by using one method selected from a group consisting of an extrusion, a spin coating, a knife coating, a vacuum deposition, and a chemical vapor deposition (CVD).

Meanwhile, the transfer layer 220 formed as part of the donor substrate 20 may be disposed to face the first electrode layer 12 formed on the acceptor substrate 10. Here, the transfer layer 220 may be transferred at a position spaced apart from the first electrode layer 12 by a determined distance or at a position at which the first electrode layer 12 and the transfer layer 220 are adhered to each other.

As illustrated FIG. 6C, the laser is irradiated in a predetermined region of the donor substrate 20. The irradiated laser is absorbed into the light-to-heat conversion layer 210 of the donor substrate 20 so as to generate heat, and the generated heat decreases adhesion between the transfer layer 220 and the light-to-heat conversion layer 210, such that the transfer layer 220 is transferred onto the acceptor substrate 10.

As a result, a transfer layer pattern 14 is formed on the first electrode layer 12 of the acceptor substrate 10. The transferring process may be performed in N₂ or a vacuum atmosphere. This is because moisture and oxygen components exist in the air, and the transfer layer pattern 14 made of an organic material may be deteriorated.

The organic layer pattern 14 formed during the transferring process may be one single-layer selected from a group consisting of the emission layer, a hole injection layer (HIL), a hole transfer layer (HTL), an electron transfer layer, and an electron injection layer (EIL), or may also be two multi-layers or more. After the transferring process, a second electrode is formed on the organic layer pattern to complete an organic light emitting element.

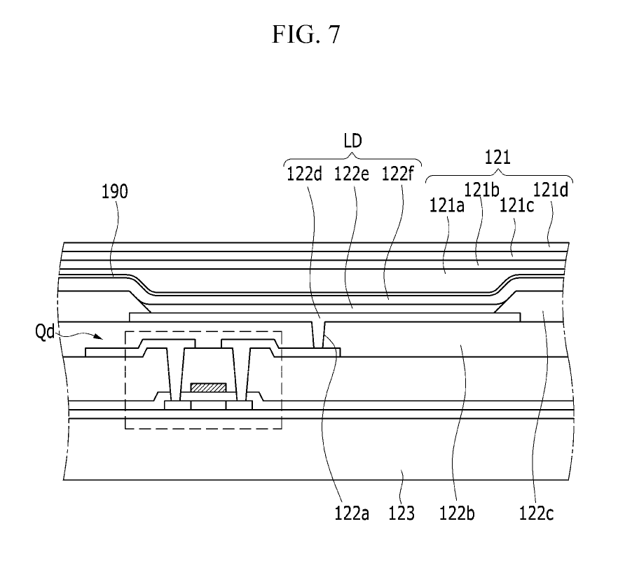

FIG. 7 is a cross-sectional view of an organic light emitting diode (OLED) display manufactured using a donor substrate.

The organic light emitting diode (OLED) display manufactured using the donor substrate according to the exemplary embodiment of the present invention will be described below with reference to FIG. 7. Referring to FIG. 7, a driving transistor Qd is formed on a display substrate 123 which may be made of a transparent glass or a plastic. Here, the acceptor substrate 10 illustrated in FIG. 6 corresponds to the display substrate 123 illustrated in FIG. 7.

A protective layer 112b, which may be made of an inorganic material or an organic material, is formed on the driving transistor Qd. When the protective layer 112b is made of the organic material, a surface of the protective layer 112b may be flat.

A via hole 122a exposing a part of the driving transistor Qd is formed in the protective layer 122b.

Furthermore, a first electrode 122d is formed on the protective layer 122b. Here, the first electrode 122d corresponds to the first electrode layer 12 illustrated in FIG. 6. The first electrode 122d may include a reflective electrode and a transparent electrode formed thereon. The reflective electrode may be made of a metal, which has high reflection, such as silver (Ag) and aluminum (Al), an alloy thereof or the like, and the transparent electrode may be made of a transparent conductive oxide such as indium tin oxide (ITO) or indium zinc oxide (IZO).

A pixel defined layer 122c is formed on the protective layer 122b while covering a circumference of an edge of the first electrode 122d.

Further referring to FIG. 7, the organic emission layer 122e is formed on the first electrode 122d. Here, the organic emission layer 122e may be formed by transferring the transfer layer 220 of the donor substrate illustrated in FIG. 6.

Furthermore, a second electrode 122f is formed on the organic emission layer 122e and the pixel defined layer 122c.

The organic emission layer 122e may further include organic layers (not illustrated) for efficiently transferring carriers of a hole or an electron to the emission layer, in addition to the emission layer (not illustrated) actually performing light emitting. The organic layers may be the hole injection layer and the hole transport layer, which are positioned between the first electrode 122d and the emission layer, and the electron injection layer and the electron transport layer, which are positioned between the common electrode 122f and the emission layer.

Also, a capping layer 190, which covers and protects the common electrode 122f, may be formed as an organic layer on the common electrode 122f.

A thin film encapsulation layer 121 is formed on the capping layer 190. The thin film encapsulation layer 121 seals and protects an organic light emitting element LD and a driving circuit unit, which are formed on the substrate 123, from the outside.

The thin film encapsulation layer 121 includes encapsulation organic layers 121a and 121c and encapsulation inorganic layers 121b and 121d, which are alternately laminated one by one. As an example, FIG. 7 illustrates a case where the thin film encapsulation layer 121 is configured by alternately laminating the two encapsulation organic layers 121a and 121c and the two encapsulation inorganic layers 121b and 121d one by one, but the present invention is not limited thereto.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for manufacturing a donor substrate, comprising the steps of:
providing a base member;
forming a coating layer on one surface of the base member;
hardening the coating layer; and
detaching the coating layer from the base member.

2. The method of claim 1, wherein:
the forming of the coating layer is performed by depositing a coating material.

3. The method of claim 2, wherein:
the coating material is an acryl-based resin.

4. The method of claim 3, wherein:
the hardening of the coating layer is performed using ultraviolet (UV).

5. The method of claim 4, wherein:
a wavelength of the ultraviolet (UV) is in a range of 200 to 400 nm.

6. The method of claim 1, wherein:
the coating layer has a thickness of at least 10 μm.

7. The method of claim 1, wherein:
in the step of detaching the coating layer, the coating layer is detached by winding the coating layer on a detaching roller.

8. The method of claim 1, wherein:
each of the steps is performed in a vacuum atmosphere.

9. The method of claim 1, further comprising the step of:
prior to the providing the base member, lowering a surface energy of the base member.

10. The method of claim 9, wherein:
in the lowering of the surface energy of the base member, the surface of the base member is fluorinated.

11. The method of claim 1, further comprising the step, after the detaching of the coating layer, of coating a transfer layer on a surface of the base member.
